(19) United States
(12) Patent Application Publication
(10) Pub. No.: US 2007/0045639 A1
(43) Pub. Date: Mar. 1, 2007

(54) Semiconductor electronic device

(75) Inventors: Sadahiro Kato, Tokyo (JP); Yoshihiro Sato, Tokyo (JP); Seikoh Yoshida, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 11/508,921

(22) Filed: Aug. 24, 2006

(30) Foreign Application Priority Data
Aug. 25, 2005 (JP) 2005-243814
Jul. 13, 2006 (JP) 2006-193241

(51) Int. Cl. H01L 33/00

(52) U.S. Cl. 257/94

(57) ABSTRACT

A semiconductor electronic device includes a buffer layer formed on a substrate, and a semiconductor operating layer that is formed on the buffer layer. The semiconductor operating layer includes a nitride-based compound semiconductor and. The buffer layer includes at least one composite layer that includes a first layer and a second layer. A lattice-constant difference between the first layer and the second layer is equal to or more than 0.2 percent.

### BACKGROUND OF THE INVENTION

1. Field of the Invention

The present invention relates to a semiconductor electronic device that includes a nitride-based compound semiconductor.

2. Description of the Related Art

Field effect transistors that include a nitride-based compound semiconductor such as a GaN system compound semiconductor have been focused on as a solid-state device capable of operating at a high temperature near 400 degree centigrade. Due to difficulty in fabricating a single crystal substrate with a large diameter from GaAs, electronic devices using the GaN system compound semiconductor are fabricated using substrates made of, for example, sapphire or silicon.

In other words, to fabricate a GaN-system field effect transistor, a GaN-system interposed layer is formed on a single-crystal sapphire substrate at a substantially low temperature of 500 to 600 degree centigrade using an epitaxial growth method such as a metal organic chemical vapor deposition (MOCVD), and a GaN layer is formed thereon at a high temperature to make a buffer layer. An electron transit layer, an electron-supplying layer, and a contact layer are formed in order on the buffer layer (hereinafter, a set of the electron transit layer, the electron-supplying layer, and the contact layer is referred to as a semiconductor operating layer). A source electrode, a drain electrode, and a gate electrode are formed on the semiconductor operating layer. In this manner, by forming the GaN layer on the low-temperature GaN-interposed layer to make a buffer layer, the GaN layers with different lattice constants are epitaxially grown on a sapphire substrate.

For example, technologies disclosed in Japanese Patent Application Laid-Open No. 2003-59948, Japanese Patent Application Laid-Open No. 2000-133601, and Japanese Patent Application Laid-Open No. H9-199759 have been known as conventional technologies.

However, when the GaN system compound semiconductor is epitaxially grown on an alternative substrate such as the sapphire substrate, lattice mismatching causes more threading dislocations at an interface between an epitaxially grown layer and the substrate. The threading dislocations extend in the direction of the epitaxial growth. There is a problem that the threading dislocations in the buffer layer deteriorate the crystallinity of the buffer layer in the field effect transistor. When the threading dislocations reach the semiconductor operating layer, they deteriorate the concentration and the mobility of two-dimensional electron gas as well as breakdown voltage characteristic of the field effect transistor. Furthermore, sometimes cracks extending from a surface of the substrate in the direction of the epitaxial growth seriously deteriorate the crystallinity.

### SUMMARY OF THE INVENTION

It is an object of the present invention to at least partially solve the problems in the conventional technology.

A semiconductor electronic device according to one aspect of the present invention includes a buffer layer formed on a substrate; and a semiconductor operating layer that is formed on the buffer layer. The semiconductor operating layer includes a nitride-based compound semiconductor and the buffer layer includes at least one composite layer that includes a first layer and a second layer. A lattice-constant difference between the first layer and the second layer is equal to or more than 0.2 percent.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross section of a field effect transistor according to a first embodiment of the present invention;

FIG. 2 is a chart indicating a state of a crack development depending on a lattice-constant difference between a first layer and a second layer;

FIG. 3 is a graph of change of a breakdown voltage with increase of the number of pairs of the first layer and the second layer;

FIG. 4 is a cross section of a field effect transistor including four pairs of the first layer and the second layer;

FIG. 5 is a cross section of a field effect transistor including a strain-inducing layer;

FIG. 6 is a graph of change of an amount of wafer-bow with increase of the thickness of the first layer;

FIG. 7 is a graph of change of leak current depending on the growth temperature of the first layer and the second layer; and

FIG. 8 is a cross section of a field effect transistor according to a second embodiment of the present invention.

### DETAILED DESCRIPTION OF THE PREFERRED EMBODIMENTS

Exemplary embodiments of the present invention are explained below in detail with reference to the accompanying drawings. The present invention is not limited to the embodiments explained below.

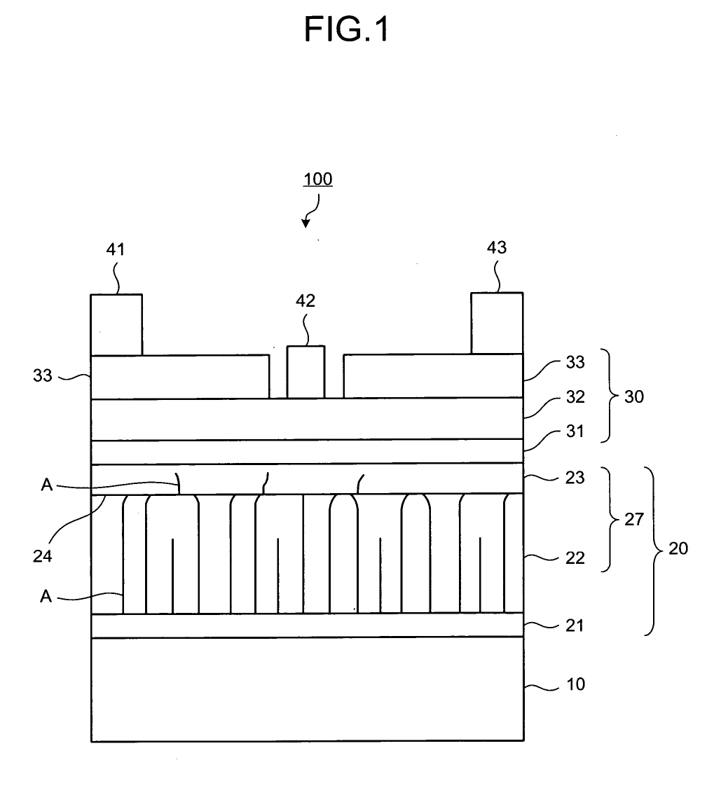

FIG. 1 is a cross section of a field effect transistor 100 as an example of a semiconductor electronic device according to a first embodiment of the present invention. The field effect transistor 100 includes a substrate 10 including Si, a buffer layer 20, a semiconductor operating layer 30, a source electrode 41 that includes Al, Ti, and Au, a gate electrode 42 that includes Pt and Au, and a drain electrode 43 that includes Al, Ti, and Au. The buffer layer 20 and the semiconductor operating layer 30 include a nitride-based compound semiconductor, and are formed on the substrate 10 in order. The source electrode 41, the gate electrode 42, and the drain electrode 43 are formed on the semiconductor operating layer 30.

The buffer layer 20 includes a buffer layer 21 that includes AlN and a composite layer 27 that includes a first layer 22 of 300-nanometer-thick undoped GaN with high resistance and a second layer 23 of 20-nanometer-thick undoped AlN. The semiconductor operating layer 30 includes an electron transit layer 31 of undoped GaN, an electron-supplying layer 32 of Si-doped AlGaN, and a contact layer 33 of heavily doped GaN. The source electrode 41 and the drain electrode 43 are formed on the contact layer 33, and the gate electrode 42 is formed on the electron-supplying layer 32.

A feature of the field effect transistor 100 is that the first layer 22 and the second layer 23 use crystalline materials with different lattice constants to form a strain interface 24 that includes a strain due to the lattice mismatching. The lattice constant of GaN in the first layer 22 is 3.189 angstrom, and that of AlN in the second layer 23 is 3.112 angstrom. As a result, the strain interface 24 prevents extension of threading dislocations A that were generated by the lattice mismatching between the substrate 10 and the first layer 22 and extended in the direction of the growth of the first layer 22.

In the field effect transistor 100 configured as above, threading dislocation density in the second layer 23 is about 1×10⁹ cm-2, which is as little as a tenth to hundredth of the threading dislocation density in the first layer 22. Moreover, mobility of two-dimensional electrons in the electron transit layer 31 is about 1200 cm²/Vs, which is about 30 percent better than a field effect transistor that has no strain interface.

In other words, the semiconductor electronic device according to the first embodiment prevents the threading dislocation from extending to upper layers by forming the first layer and the second layer from crystalline materials with different lattice constants and thus generating a strain (stress) between the first layer and the second layer.

While the field effect transistor 100 includes GaN in the first layer 22 and AlN in the second layer 23, the first layer 22 and the second layer 23 can include AlₓGa₁₋ₓN with varied relative proportions of Al and Ga. To use such a disorder phase, the lattice constant of it can be estimated from the lattice constants of AlN and GaN using Vegard's law. Moreover, the first layer 22 and the second layer 23 can include other elements as needed.

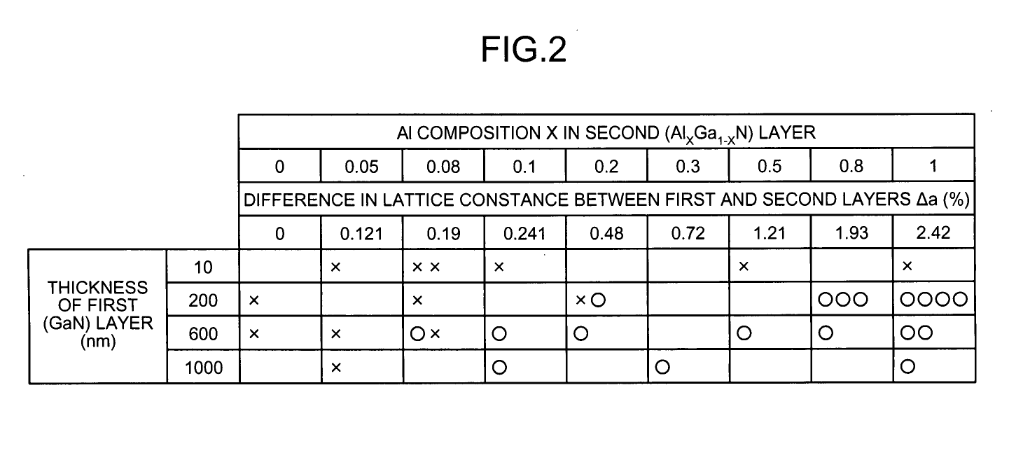

FIG. 2 is a chart indicating a state of a crack development when the field effect transistor 100 is fabricated using AlₓGa₁₋ₓN in the second layer 23. A “x” in the chart indicates the field effect transistor 100 that generated a crack reaching the semiconductor operating layer 30 therein, and a “O” indicates the field effect transistor 100 that generated no crack therein. The presence of the crack is indicated in the chart with respect to the lattice-constant difference between the first layer 22 and the second layer 23 represented as Δa, and the thickness of the first layer 22.

Each of the field effect transistors 100 used in FIG. 2 includes a substrate of Si and four composite layers 27 layered on the substrate. In other words, four pairs of the first layer 22 and the second layer 23 are layered alternately on the substrate 10. Each of the second layers 23 is 30 nanometers thick. The lattice-constant difference between the first layer 22 and the second layer 23 varies depending on the relative proportions of Al in the second layer 23 that is represented as x, and is calculated from the lattice constant a1 of the first layer 22 and the lattice constant a2 of the second layer 23 using the following equation.
Δa=|1−a2/a1|×100

From the results shown in FIG. 2, it is found that cracks reaching the semiconductor operating layer 30 can be prevented at a high rate by setting the Δa to 0.2 percent or more and the thickness of the first layer 22 to equal to or more than 200 nanometers and equal to or less than 1,000 nanometers, and as a result, the field effect transistor 100 with a high breakdown voltage is obtained. The Δa is preferably less than the lattice-constant difference between the semiconductor operating layer 30 and the substrate 10, more specifically 20 percent or less.

It is assumed that the cracks can be reduced by the first layer 22 with 200 nanometers or more thickness for the following reason. When the first layer 22 is not sufficiently thick, it is affected by an adjacent layer on the opposite side of the second layer 23, which prevents generation of sufficient compressive strain or tensile strain between the first layer 22 and the second layer 23. The lack of the strain is alleviated by making the first layer 22 equal to or thicker than 200 nanometers, and eventually the cracks are reduced. On the contrary, it is not desirable to make the first layer 22 thicker than 1,000 nanometers because a process of fabricating the field effect transistor 100 with so thick a layer takes a very long time.

While the field effect transistor 100 herein uses the 30-nanometer-thick second layer 23, the thickness of the second layer 23 is not limited to be 30 nanometers and the preferable thickness is equal to or more than 0.5 nanometer and equal to or less than 200 nanometers. If the second layer 23 is too thin, the sufficient strain cannot be generated between the first layer 22 and the second layer 23, and thus reduces an effect of bending the dislocation. If the second layer 23 is too thick, the strain is so large that new dislocations are generated from the second layer 23.

In general, it is not easy to grow the GaN layer thick on the Si substrate. For example, when a single AlN layer is used as a buffer layer, cracks are generated on the surface of the GaN layer at the thickness of 300 nanometers. However, in the field effect transistor 100 according to the first embodiment, the GaN layer can grow to 1,000 nanometers on the buffer layer 20 without any crack.

While the field effect transistor 100 includes a single composite layer 27 in the first embodiment, the field effect transistor 100 can include more than one composite layer 27. A plurality of the composite layers 27 further reduces the threading dislocations that extend to the semiconductor operating layer 30, and thereby it is possible to obtain a field effect transistor with even higher breakdown voltage.

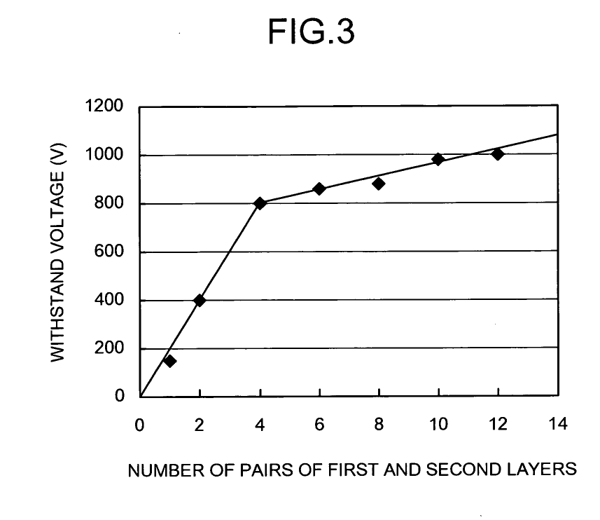

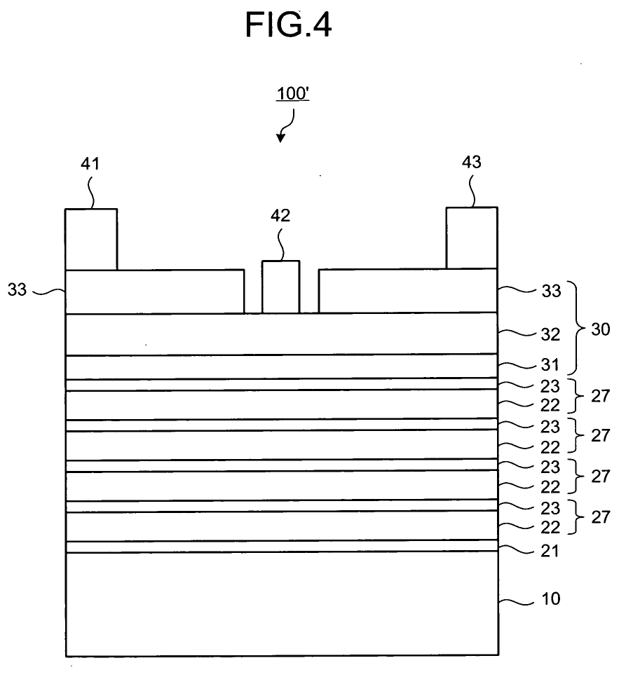

FIG. 3 is a graph change of a breakdown voltage with increase of the number of pairs of the first layer and the second layer, namely the number of the composite layers 27. The composite layer used in FIG. 3 includes the first layer of 200-nanometer-thick GaN and the second layer of 30-nanometer-thick AlN alternately layered therein. From the result, it is found that the breakdown voltage of the field effect transistor improves as more composite layers 27 are layered. In particular, four or more composite layers 27 provide generally higher breakdown voltage. FIG. 4 is a cross section of a field effect transistor 100′ that includes four composite layers 27.

While the field effect transistor 100 herein includes the composite layer 27 in which the second layer 23 is formed on the first layer 22, a strain-inducing layer can be formed between the first layer 22 and the second layer 23. The strain-inducing layer can include, for example, a crystalline material with the intermediate lattice constant between the lattice constants of the crystalline material in the first layer 22 and the crystalline material in the second layer 23, or a gradient material whose composition gradually changes in the direction of the layers.

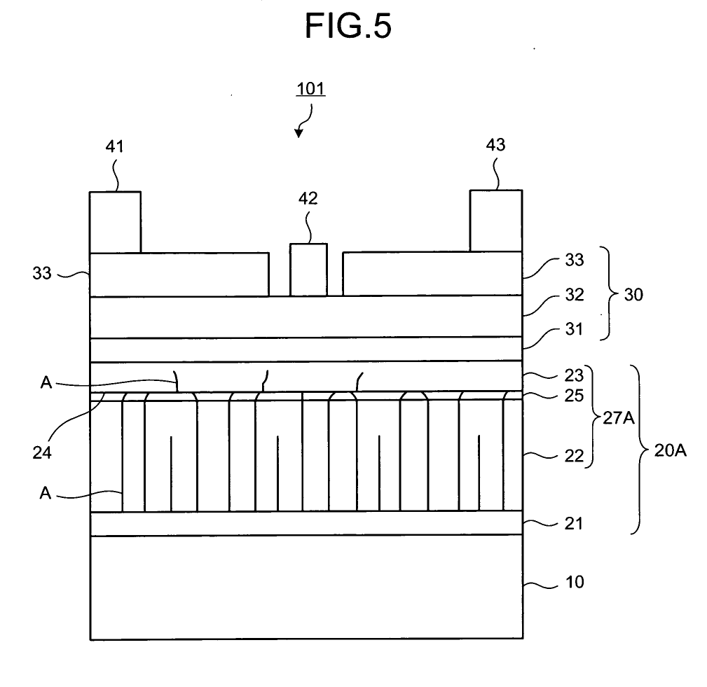

FIG. 5 is a cross section of a field effect transistor 101 including a strain-inducing layer 25. The field effect transistor 101 is similar to the field effect transistor 100 except that it includes a buffer layer 20A including the buffer layer 21 and a composite layer 27A in which the first layer 22, the strain-inducing layer 25, and the second layer 23 are layered in the order, instead of the buffer layer 20.

A conventional technology uses a strain-relaxation layer that includes, for example, the first layers of GaN and the second layers of AlN alternately layered with the thickness of each layer equal to or less than 20 nanometers. Thickness of each layer is equal to or less than 20 nanometers because the crystallinity does not seriously deteriorate with this thickness when the critical film thickness is taken into account. However, the conventional method involves a problem that the amount of the wafer-bow is as much as about 100 micrometers when, for example, a four-inch epitaxial wafer is used. The amount of the wafer-bow is a difference between a maximum height and a minimum height on the surface of the wafer, which is preferably 50 micrometers or less in a semiconductor electronic device fabrication process.

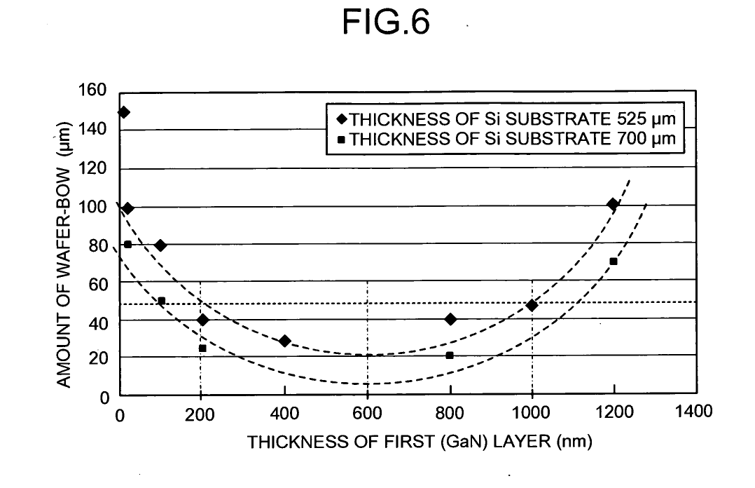

On the contrary, the first layer 22 of the field effect transistor 100 according to the first embodiment is the GaN layer with the thickness equal to or more than 200 nanometers and equal to or less than 1,000 nanometers. This limits the amount of the wafer-bow to 50 micrometers or less when the four-inch epitaxial wafer is used as the substrate 10. FIG. 6 is a graph of an actual amount of wafer-bow of the substrate 10 depending on thickness of the first layer 22. The graph indicates actual measurements of the wafer-bow on a 525-micrometer-thick Si substrate and a 700-micrometer-thick Si substrate used as the substrate 10. The field effect transistor 100 used herein includes 30-nanometer-thick second layers 23 and four composite layers 27.

From the results shown in FIG. 6, it is found that the wafer-bow on the substrate 10 can be minimized by forming the first layer 22 with 600 nanometers thickness regardless of the thickness of the substrate 10 itself. It is also found that, when the diameter of the substrate 10 is four inches, the amount of the wafer-bow can be reduced to 50 micrometers or less by forming the first layer 22 with the thickness of 600±400 nanometers, namely equal to or more than 200 nanometers and equal to or less than 1,000 nanometers. In this manner, the preferable thickness of the first layer 22 to limit the amount of the wafer-bow to 50 micrometers or less depends on the diameter of the wafer, i.e. the substrate 10, and is generally represented as 600 nanometers plus or minus a predetermined value. It was confirmed that the optimal thickness of the first layer 22 is also 600 nanometers when the diameter of the substrate 10 is six inches.

One approach to relax the strain is to grow the second layer with AlN at 600 degree centigrade or lower temperature and thereby promote the three-dimensional growth. In this case, however, because the growth temperature of the first layer is 1,000 degree centigrade or higher, it is required to lower the temperature after the first layer is grown and raise the temperature after the second layer is grown at 600 degree centigrade. As a result of this, the growing process needs a long time, and the crystallinity seriously deteriorates after the surface of the crystalline material is exposed to high temperature for the long time while the epitaxial growth suspends to change the temperature.

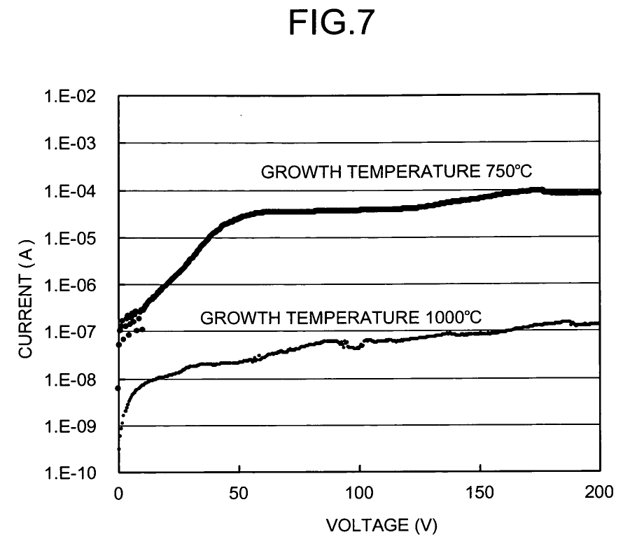

On the contrary, the second layer 23 in the field effect transistor 100 grows at 900 degree centigrade or higher, which is close to the growth temperature of the first layer 22. Therefore, the surface of the crystalline material does not have to be exposed to the high temperature for so long a time, and thus the crystallinity does not deteriorate. In addition, it is found from experiment that the growth temperature of 1,300 degree centigrade deteriorates the crystallinity. The preferable growth temperature of the first layer and the second layer is 1,300 degree centigrade or lower. The more preferable growth temperature of the first layer and the second layer is equal to or more than 950 degree centigrade and equal to or less than 1,200 degree centigrade, where the single crystal can grow. Moreover, as shown in FIG. 7, growing the first layer and the second layer within the preferable temperature range reduces leak current in the field effect transistor 100.

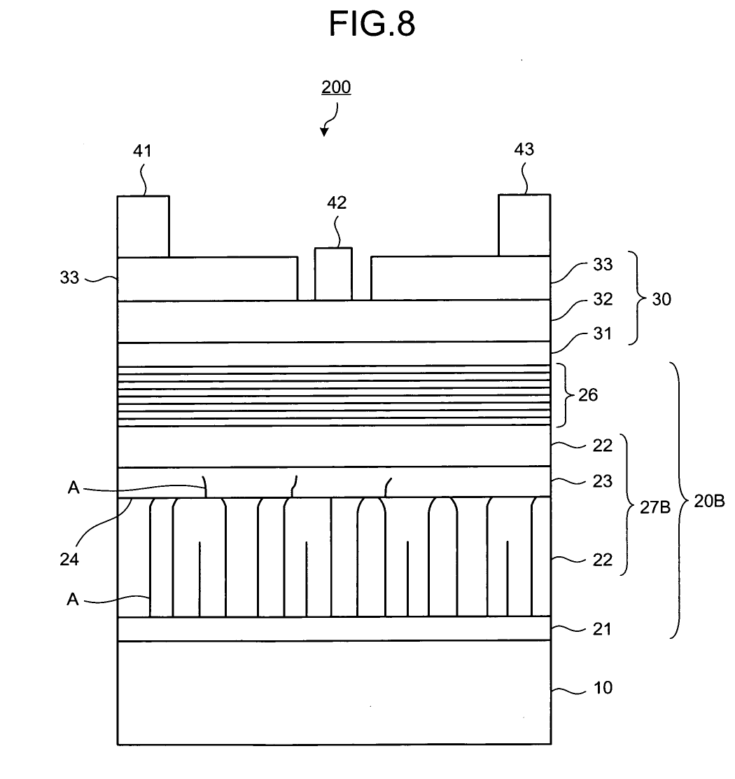

FIG. 8 is a cross section of a field effect transistor 200 according to a second embodiment of the present invention. The field effect transistor 200 is similar to the field effect transistor 100 except that it includes a buffer layer 20B instead of the buffer layer 20. The buffer layer 20B includes a composite layer 27B and a superlattice layer 26 between the composite layer 27B and the semiconductor operating layer 30. The superlattice layer 26 includes 10 pairs of a 30-nanometer-thick GaN layer (a fourth layer) on a 5-nanometer-thick AlN layer (a third layer) layered therein.

The composite layer 27B includes an extra first layer 22 on the second layer 23. This is based on the fact that the semiconductor electronic device according to the second embodiment is not limited to include the same number of the first layer and the second layer in the composite layer therein.

The superlattice layer 26 between the second layer 23 and the semiconductor operating layer 30 prevents negative effects on the electron transit layer 31 by electrons activated by piezoelectric polarization on the strain interface 24. This can be achieved because the interfaces of the third layer and the fourth layer in the superlattice layer 26 are close enough to cause no piezoelectric polarization.

The third layer and the fourth layer that form the superlattice layer 26 use crystalline materials with the different lattice constants as with the case of the first layer 22 and the second layer 23. The third layer and the fourth layer can use the same materials as those used in the first layer 22 and the second layer 23 respectively, or they can also use materials different from those in the first layer 22 and the second layer 23.

The first and second embodiments described above do not limit technical scope of the present invention. For example, the semiconductor electronic device is not limited to the field effect transistor but can be a high electron mobility transistor; the nitride-based compound semiconductor is not limited to GaN or AlN but can be AlₓIn_{y}Ga_{1-x-y}AsᵤPᵥN₁₋ᵤ₋ᵥ (0≦x≦1, 0≦y≦1, x+y≦1, 0≦u≦1, 0≦v≦1, u+v<1); and the semiconductor electronic device can include a plurality of strain-inducing layers.

According to an embodiment of the present invention, the strain interface is provided between the first layer and the second layer in the buffer layer on a heterogeneous substrate. This reduces the extension of the threading dislocations to the semiconductor operating layer and occurrence of the cracks to improve the crystallinity of the buffer layer, and improves the breakdown voltage without deteriorating the concentration and the mobility of two-dimensional electron gas.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor electronic device comprising:
a buffer layer formed on a substrate; and
a semiconductor operating layer that is formed on the buffer layer, the semiconductor operating layer including a nitride-based compound semiconductor and, wherein
the buffer layer includes at least one composite layer that includes a first layer and a second layer, and
a lattice-constant difference between the first layer and the second layer is equal to or more than 0.2 percent.

2. The semiconductor electronic device according to claim 1, wherein
the composite layer further includes a strain-inducing layer between the first layer and the second layer, the strain-inducing layer having a lattice constant equal to or higher than that of the first layer and equal to or lower than that of the second layer.

3. The semiconductor electronic device according to claim 1, wherein
a thickness of the first layer is in a range between 200 nanometers and 1,000 nanometers.

4. The semiconductor electronic device according to claim 1, wherein
a thickness of the first layer is 600 nanometers ± a predetermined value, and
the predetermined value is determined based on a diameter of the substrate.

5. The semiconductor electronic device according to claim 4, wherein
the predetermined value is 400 nanometers when the diameter of the substrate is four inches.

6. The semiconductor electronic device according to claim 3, wherein
a thickness of the second layer is in a range between 0.5 nanometer and 200 nanometers.

7. The semiconductor electronic device according to claim 4, wherein
a thickness of the second layer is in a range between 0.5 nanometer and 200 nanometers.

8. The semiconductor electronic device according to claim 1, wherein
the buffer layer includes at least four composite layers.

9. The semiconductor electronic device according to claim 1, wherein
the buffer layer further includes a superlattice layer including a third layer and a fourth layer alternately layered, between the composite layer and the semiconductor operating layer.

10. The semiconductor electronic device according to claim 9, wherein
a thickness of each of the third layer and the fourth layer is in a range between 0.5 nanometer and 20 nanometers.

11. The semiconductor electronic device according to claim 1, wherein
a growth temperature for at least the first layer and the second layer is in a range between 900 degree centigrade and 1300 degree centigrade.
